(19) United States
(12) Patent Application Publication
(10) Pub. No.: US 2004/0080056 A1
(43) Pub. Date: Apr. 29, 2004

(54) Packaging system for die-up connection of a die-down oriented integrated circuit

(76) Inventors: David Chong Sook Lim, Penang (MY); Hun Kwang Lee, Penang (MY); Howard Allen, Limington, ME (US); Stephen Martin, South Portland, ME (US)

Correspondence Address: CESARI AND MCKENNA, LLP, 88 BLACK FALCON AVENUE, BOSTON, MA, 02210, US

(21) Appl. No.: 10/664,982

(22) Filed: Sep. 17, 2003

Related U.S. Application Data
(63) Continuation-in-part of application No. 09/823,600, filed on Mar. 30, 2001.

(51) Int. Cl. H01L 23/49

(52) U.S. Cl. 257/784; 257/780; 438/617

(57) ABSTRACT

A die attach package for connecting a die or chip of die-down orientation to a printed circuit board in a die-up orientation. The package includes a substrate with leads that may be traces terminating in vias or that may be the leads of a lead frame. The traces or the leads of the lead frame are modified such that they pass under the die when the die is attached. A flattened ball is attached to die contacts and a gold wire runs parallel to the die and then to a via on the substrate. The wire may be attached to the flattened ball by a wedge technique or other such known techniques. The die is attached to the substrate using a non-electrically-conductive material. This packaging enables a fabricator to make die of one orientation type, die down, and use that die in a die-up package, thereby saving on fabrication costs.

### CROSS-REFERENCE TO RELATED APPLICATIONS

The present application is a continuation-in-part of commonly assigned co-pending U.S. patent application Ser. No. 09/823,600, which was filed on Mar. 30, 2001, by David Chong, et al. for a PACKAGING SYSTEM FOR DIE-UP CONNECTION OF A DIE-DOWN ORIENTED INTEGRATED CIRCUIT and is hereby incorporated by reference.

### BACKGROUND OF THE INVENTION

1. Field of the Invention

The present invention relates to integrated circuit packaging. More particularly, the present invention relates to the arrangement for attaching a die-down-oriented integrated circuit in a die-up-oriented package such a chip scale package land grid array or a lead frame.

2. Description of the Prior Art

Integrated circuits are connected to other integrated circuits or other electrical devices via printed circuit boards having metal connectors. The integrated circuits are formed on sections of semiconductor wafers or die using well-known fabrication techniques. An integrated circuit of a die is attached to a substrate designed to provide structural support, thermal protection, and a means to fan out metal connectors or traces from the circuit to the printed circuit board. The combination of the integrated circuit and its substrate/metal connectors is referred to as the integrated circuit package. The package is essentially a housing that is used either to plug the device into sockets of the circuit board or to solder the device onto surface contacts of the board.

The most common type of semiconductor packaging to have been used is the small-scale outline package such as shown in FIG. 1. That package includes a semi-conductor chip 10 supported on and attached to a die attach pad (DAP) 11 encapsulated in an encapsulating material 12. The chip 10 includes bond pads represented by pads 13 and 14 connected to bond wires 15 and 16 that are connected to respective lead frames 17 and 18 of a lead frame. The lead frame connects the chip 10 are located on the top surface of the chip 10. The desired connection of the chip 10 to the printed circuit board has pads 13 and 14 connected to the lead frames 17 and 18 on the same side of the package.

FIG. 2 illustrates an alternative package design. That package includes mounting of the die or chip 20 on a DAP 21. Contacts 22 and 23 of the chip 20 are coupled to a bottom side of the lead frame by way of wire bonds 24 and 25 to lead frame leads 26 and 27. The construction process for producing the package of FIG. 2 is substantially the same as the process used to produce the package of FIG. 1. The package of FIG. 2 is commonly referred to as a die-down package while that of FIG. 1 is a die-up package.

The packaging types described must be designed with common connector protocols in mind. That is, there are conventions for the ways in which electronic devices are interconnected, requiring the chip manufacturers to fabricate chips and, more specifically, their contacts, with a particular orientation. The contact pads of the packages shown in FIGS. 1-3 must be positioned to match the mounting configuration established on the printed circuit board. For example, a chip to be coupled to a high-potential power rail, a low potential power rail, two inputs and two outputs must be configured so that the chip's contacts are matched to the traces associated with each of those elements. For a die-down package such as the package shown in FIG. 2, the chip is fabricated so that its contacts are on what becomes the bottom of the structure. Thus, there are two types of chip orientations that must be fabricated as a function of the particular packaging type employed. Those chips that are “die-down” and those that are “die-up.” While it is common practice to fabricate both types of die orientations, it would be more cost effective to be able to fabricate just one type that could be used in either type of package configuration.

Wire bonding techniques for connecting integrated circuit dies to packages that are mounted on printed circuit boards are known in the art. Such techniques usually include forming a ball on the end of a gold wire. The ball is attached to the bond pad on the die and the wire is looped up and out towards the lead frame contact. The end is wedge or stitch bonded to the lead frame. One issue with such techniques is that the wire loop rises upward thereby dictating a higher, larger finished package. See FIG. 1.

Therefore, what is needed is a packaging arrangement that would permit the connection of a die-down chip in a die-up configuration.

### SUMMARY OF THE INVENTION

It is an object of the present invention to provide a packaging arrangement that would permit the connection of a die-down chip in a die-up configuration.

This and other objects are achieved in the present invention by providing a connection substrate with traces or connection lines that run under the die. The die is a die fabricated as a die down one that is positioned on the substrate with the contacts on the side opposite that of the substrate so that it is in a die up position. Ordinarily, a die down die having its contacts located on the exposed side of the die would not be connectable in a die up package because the contacts of the die would be adjacent to the wrong traces or pins of the substrate. However, the substrate of the present invention includes those traces or pins as passing from one side of the die to the other so that correct connections may be established. Specifically, the connectors are routed under the die, allowing a die-down design to be wire bonded in a die-up package while maintaining the same external configuration associated with a die-up package while maintaining the same external configuration associated with a die-up package. The substrate may be a ceramic or organic substrate or a standard lead frame. An electrically non-conductive attach material is used to connect the die to the substrate.

The packaging arrangement of the present invention allows a die manufacturer to fabricate die-down oriented die that may be used in a die-up package as well as a die-down package. Further since, the die may be coupled to a circuit board using connectors and traces, it is suitable for coupling a die-down die in a package that may otherwise be too small for flip chip packaging.

In a preferred embodiment of the present invention, when the inventive substrate is used to reconfigure the pin out of the chip, the present invention provides for a bond stitch on ball wire bonding technique that reduces the height of the wire bond loop compared to the prior art, and thus the finished package.

These and other advantages of the present invention will become apparent upon review of the following detailed description, the accompanying drawings, and the appended claims.

### BRIEF DESCRIPTION OF THE DRAWINGS

FIG. 1 is a cross-sectional side view of a lead frame-based die-up package of the prior art.

FIG. 2 is a cross-sectional side view of a lead frame-based die-down package of the prior art.

FIG. 3 is a perspective view of the die-down/die-up orientation package of the present invention with a die in place on a ceramic substrate.

FIG. 4 is a top view of the substrate of the package of the present invention showing the trace routings that run under the die when in place.

FIG. 5 is top view of the package of the present invention without the die in place on the substrate.

FIG. 6 is a perspective view of a second embodiment of the die-down/die-up orientation package of the present invention with a die in place on a lead frame.

FIG. 7 is a side view of a flattened ball on a die and a wire bond to the substrate.

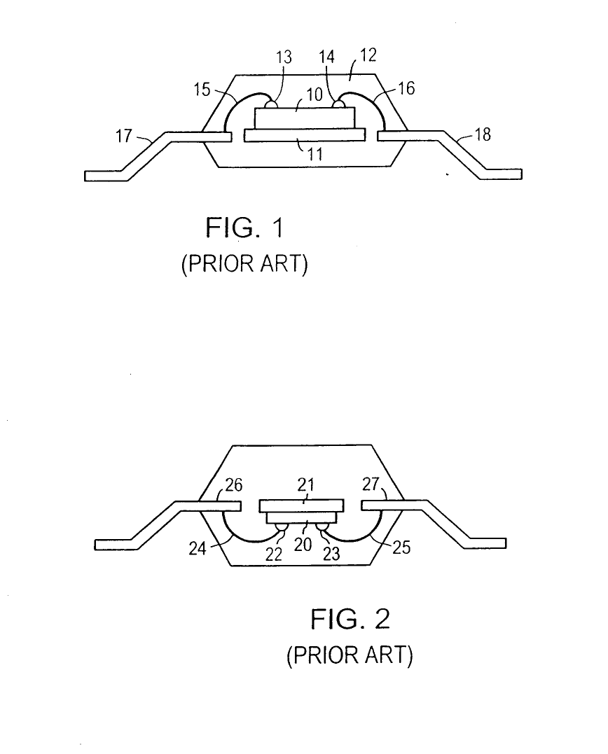

### DESCRIPTION OF THE PREFERRED EMBODIMENTS OF THE INVENTION

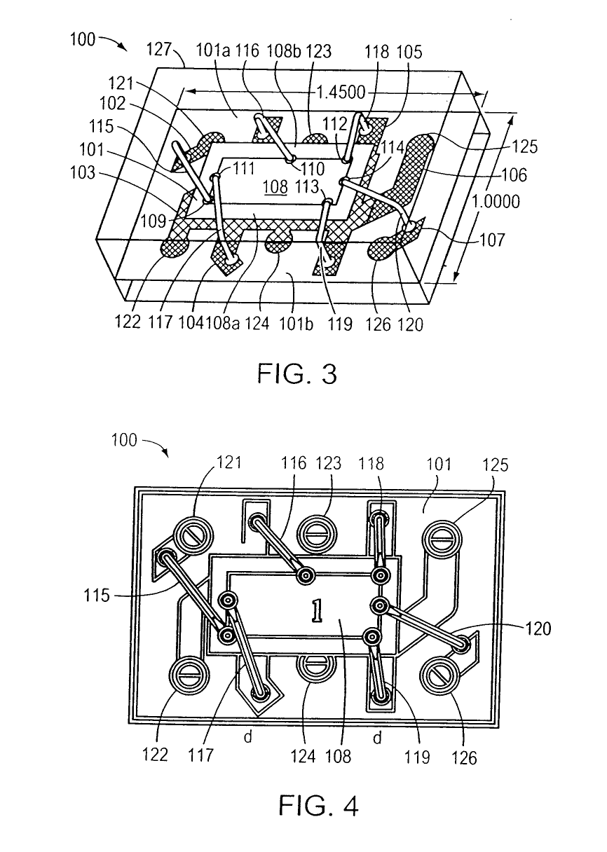

A die package 100 of the present invention is shown in FIGS. 3 and 4. The package 100 includes a substrate 101 with a plurality of patterned traces 102-107 that provide connections from a die 108 to a printed circuit board (not shown). Although six traces have been shown, it is to be understood that more or fewer may be applied to the substrate 101 as a function of the particular contact requirements associated with the active components of the die 108. For the packaging arrangement shown in the drawings, the die 108 is of a die-down type such that its conductive contact 109-114 would ordinarily be positioned to provide proper pinout when the die 108 is attached to the bottom the substrate 101. That is, the die package 100 of the present invention enables orientation of the die 108 in a die up arrangement although the die 108 is fabricated with a die down orientation. The contacts 109-114 are connected to the traces 102-107 by way of connector wires 115-120. The arrangement of the wires 115-120 and the traces 102-107 effectively “flip-flop” the orientation of the contacts 109-114 so that proper coupling to vias 121-126 connected to the underlying printed circuit board is established.

The substrate 101 may be fabricated as a ceramic substrate or an organic substrate. It includes a first side 101a and a second side 101b. The die 108 is physically connected to the substrate 101 using a non-electrically-conductive material such as a thermally conductive epoxy, for example. The die 108 includes a first side 108a and a second side 108b, such that the first side 108a is opposite the first side 101a of the substrate 101. The same opposing relation can be said for the second side 108b of the die 108 and the second side 101b of the substrate 101. It is important that the die 108 not contact the substrate 101 directly in order to avoid shorting. In that regard, it is desirable to ensure that the adhering material spaces the die 108 from the substrate 101 while maintaining adequate physical support. The package 100 further includes an encapsulant 1127 to seal the die 108 and connectors in to protect the substrate 101 and wire bonding stability. The traces 102-107 may be applied to the substrate 101 after substrate formation or as part of the substrate fabrication process.

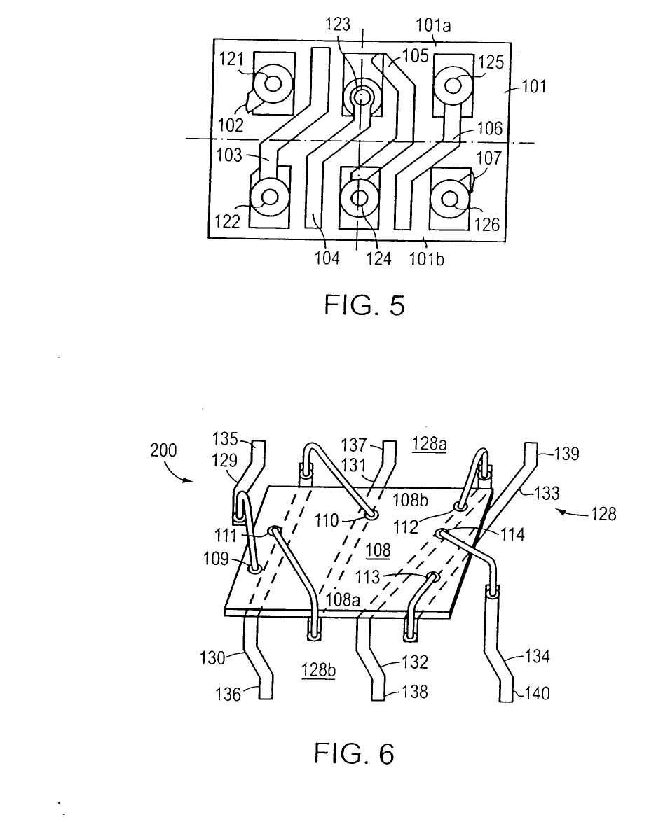

As illustrated in FIG. 5, the traces 102-107 on the substrate 101 are arranged to pass under the die 108 when the die 108 is attached to the substrate 101. The traces 102-107 are routed in an organized manner so that the contacts of the die 108 on the first side 108a are electrically connected to traces having vias on the second side 101b of the substrate 101 and the contacts on the second side 108b are electrically connected to traces having vias on the first side 101a of the substrate 101. As indicated, the traces 102-107 and the vias 121-126 may be established on the substrate 101 in any well known manner. A goal of the present invention shown in the drawings is to electrically connect contacts on the side of the die 108 to vias on the opposite side of the substrate 101. More Generally, the present invention is directed to arranging traces and wire contacts so that a die-down die may be packaged in a die-up orientation.

Although the present invention has been described as a package system 100 designed to couple the die 108 to a substrate 101 including traces 102-107, it may alternatively be configured as an arrangement to couple the die 108 to a lead frame 128, as shown in FIG. 6. The package 200 of FIG. 6 includes a plurality of leads 129-134 that provide connections from the die 108 to a printed circuit board (not shown). Although six leads have been shown, it is to be understood that more or fewer may be applied as a function of the particular contact requirements associated with the active components of the die 108. For the packaging arrangement shown, the die 108 is of a die-down type such that its conductive contacts 109-114 would ordinarily be positioned for mounting the die 108 to the bottom side of the leads 129-134. That is, the die package 200 of the present invention enables orientation of the die 108 in a die up arrangement although the die 108 is fabricated with a die down orientation. The contacts 109-114 are connected to the leads 129-134 by way of connector wires 115-120. The arrangement of the wires 115-120 and the leads 129-134 effectively “flip-flop” the orientation of the contacts 109-114 so that proper coupling to paddle contacts 135-140 connected to the underlying printed circuit board is established. The leads 129-134 may then be connected to a printed circuit board in a well-known manner.

As illustrated in FIG. 6, the leads 129-134 of the lead frame 128 are arranged to pass under the die 108 when the die 108 is attached to the lead frame 128. The leads 129-134 are routed in an organized manner so that contacts of the die 108 on its first side 108a are electrically connected to paddles having circuit board contacts on a second side 128b of the lead frame 128 and the contacts on the second side 108b of the die 108 are electrically connected to paddles having board contacts on a first side 128a of the lead frame 128. The leads 129-134 may be fabricated in any well-known manner. The die 108 is connected to the lead frame 128 using a thermally conductive and electrically non-conductive material. The package 200 of FIG. 6 arranges the lead frame leads 129-134 so that a die-down die may be packaged in a die-up orientation.

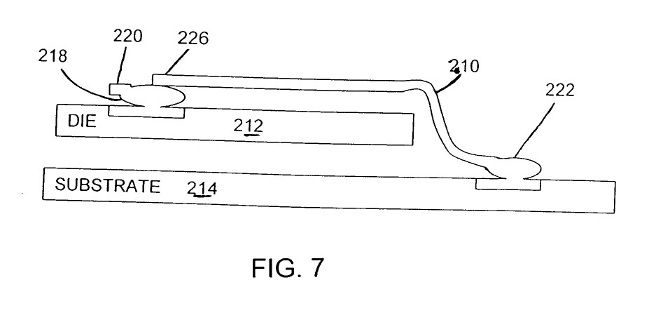

FIG. 3 shows wires (119, 120, etc.) that connect the die pads 113, 114, etc) to the substrate 101. Compare the wire connections of FIG. 3 and that of FIG. 7. Note that, in FIG. 7, the wire 210 does not loop upward but lie substantially flat and substantially parallel to the die surface 212 and then bends downward to the substrate 214. The techniques used to fashion this arrangement include forming a ball at the end of a gold wire and attaching the ball to the bond pad 216 on the die. The ball is then flattened 218 while pinching off the wire leaving a stub 220. Another ball 222 is formed at the end of a gold wire 210 and attached by known ball bonding techniques (e.g. wedge, solder, etc.) to the contact 224 on the substrate. The free end 226 of that wire is then looped toward to the die pad with the flattened ball. The wire runs parallel and near the die surface to a die contact with a flattened ball. The free end of the wire is wedge or stitched 228 to the flattened ball as shown in FIG. 7.

While the invention has been described with reference to particular example embodiments, it is intended to cover all modifications and equivalents within the scope of the following claims.

What is claimed is:

1. A die containing package comprising:
a die defining electrical die contacts,
a substrate defining first substrate contacts,
flattened electrical conductive balls attached to the die contacts and making electrical connection thereto,
electrical conductive runs on the substrate connecting the first substrate contacts to second substrate contacts,
electrically conductive wires with one end connected to the first substrate contacts, wherein the wires are formed to run substantially parallel to the surface of the die to the die contacts,
means for making electrical connection between the die contacts and the other end of the wires.

2. The die containing package of claim 1 further comprising:
a frame defining first leads defining first frame contacts, and
means for making electrical connections between the first frame contacts and the second contacts on the substrate.

3. The die containing package of claim 1 wherein the second substrate contacts are located on the substrate opposite the first substrate contacts.

4. The die containing package of claim 1 wherein the second substrate contacts are located on the substrate to accommodate a pin out different from the die.

5. A process for packaging a die comprising the steps of:
defining electrical die contacts,
defining a substrate with first substrate contacts,
flattening an electrical conductive balls,
attaching the flattened electrically conductive ball to the die contacts,
forming electrical conductive runs on the substrate connecting the first substrate contacts to second substrate contacts,
connecting electrically conductive wires to the first substrate contacts,
running the electrically conductive wires substantially parallel to the surface of the die to the die contacts, and
making electrical connection between the die contacts and the other end of the wires.

6. The process of claim 5 further comprising the steps of:
defining etched runs with first electrical contacts on the printed circuit board,
providing a frame,
defining first frame contacts on the frame,
defining first leads on the frame,
making electrical connections between the first frame contacts and the second contacts on the substrate.

7. The process of claim 5 further comprising the step of locating the second substrate contacts on the substrate opposite the first substrate contacts.

8. The process of claim 5 further comprising the step of locating the second substrate contacts on the substrate to accommodate a pin out different from the die.
